(19) United States
(12) Patent Application Publication
(10) Pub. No.: US 2001/0008384 A1
(43) Pub. Date: Jul. 19, 2001

(54) Method for generating frequencies in a dual phase locked loop

(75) Inventor: Do-Il Ku, Suwon-shi (KR)

Correspondence Address: Paul J. Farrell, Esq., DILWORTH & BARRESE, 333 Earle Ovington Boulevard, Uniondale, NY, 11553, US

(73) Assignee: Samsung Electronics Co. Ltd.

(21) Appl. No.: 09/752,599

(22) Filed: Dec. 29, 2000

(30) Foreign Application Priority Data
Dec. 30, 1999 (KR) 1999-67405

(51) Int. Cl. H03L 7/07; H03L 7/18

(52) U.S. Cl. 331/2; 331/25; 455/316; 455/318

(57) ABSTRACT

A method for generating frequencies in a dual phase locked loop (PLL). The method comprises the steps of: generating radio frequency local oscillations (RFLO) sequentially increased in the bandwidth at a given interval of more than two channels; and generating a group of intermediate frequency local oscillations (IFLO) gradually increased from a reference frequency channel by channel in said given interval, wherein said group of IFLOs are sequentially repeated at said given interval.

### BACKGROUND OF THE INVENTION

1. Field of the Invention

The present invention relates to an intermediate circular orbit (ICO) communications system used for GMPCS (Global Mobile Personal Communication by Satellite), and more particularly to a method for generating selected intermediate frequency local oscillations (IFLO) and radio frequency local oscillations (RFLO).

2. Description of the Related Art

Conventionally, the method for synthesizing transmitted or received frequencies is to generate a desired frequency only by jumping RFLO without changing IFLO. Although making it possible to readily obtain desired frequencies, this method may hardly apply to a communications system requiring a short lock time and a wide bandwidth such as the ICO communications system.

The frequency synthesizer with a single phase locked loop (PLL) comprises a reference oscillator, a phase detector, a loop filter, a voltage-controlled oscillator (VCO), and a programmable counter (PC) or frequency divider. Compared to this, the frequency synthesizer having dual PLL comprises a temperature controlled VCO, two phase detectors, two frequency dividers, two loop filters, and two VCOs.

When the frequency synthesizer is provided with a dual PLL, one PLL part serves to provide the RFLO, and the other the IFLO, so as to generate a desired carrier frequency Fc. The frequency synthesizer with the dual PLL is widely used for FDMA (Frequency Division Multiple Access)communications systems. For frequency allocation in the FDMA system, the integer-N frequency divider of the IF local oscillator and the fractional-N frequency divider of the RF local oscillator are supplied with 24-bit control data from the base band circuit. The integer-N frequency divider generates a single IFLO providing a constant frequency without jumping under the control of the base band circuit. Meanwhile, the fractional-N frequency divider generates different RFLOs providing different frequencies graded by a constant interval according to channels. For example, the receiver of the ICO communications system has a constant IFLO of 456.0 MHz and RFLOs increased by 25 KHz. In the transmitter, the IFLO of 430.0 MHz is multiplied by ½to generate the output frequency of 215.0 MHz applied to the mixer, whose other input is supplied with an RFLO of (2200+0.025*n) MHz. Thus, the output of the mixer is {(2200+0.025*n)−215} MHz=(1985+0.025*n) MHz for transmission carrier frequencies of the ICO communications system with a channel width of 25 KHz. Likewise, the receiver has a fixed IFLO of 456.0 MHz applied to the mixer, whose other input is supplied with RFLOs ranging by intervals of 25 KHz.

Thus employing such a conventional method for arranging the frequencies of the GMPCS system, the RFLO should be increased by intervals of 25 KHz that is the frequency bandwidth per channel of the ICO communications system. This results in the comparison frequency of the PLL for RFLO being 25 KHz, so that the maximum comparison frequency of RFLO only becomes 400 KHz (25 KHz*16) even with a fractional-N frequency divider of modulus 16. The comparison frequency is an important factor determining the lock time in the system. As the comparison frequency becomes greater, the lock time becomes shorter. Usually having 1199 channels, the ICO communications system requires a lock time of 350 μs. Thus, the increased channels require a shorter lock time, which may be readily achieved by increasing the value of the comparison frequency.

However, the conventional system suffers the drawback that the comparison frequency cannot be easily changed. Moreover, it increases the bandwidth of the VOC for RFLO which may generate phase errors and phase noises.

### SUMMARY OF THE INVENTION

It is an object of the present invention to provide a method for generating frequencies with a short lock time in a mobile station using a dual PLL.

It is another object of the present invention to provide a method for preventing phase errors in a mobile station using a dual PLL.

It is still another object of the present invention to provide a method for preventing phase noises in a mobile station using a dual PLL.

It is further another object of the present invention to provide a method for optimizing the frequency characteristics of a mobile station using a dual PLL.

According to an aspect of the present invention, a method for generating frequencies in a dual PLL comprises the steps of generating RFLOs sequentially increased in the bandwidth at a given interval of more than two channels, and generating a group of IFLOs gradually increased from a reference frequency channel by channel in the given interval, wherein the group of IFLOs are sequentially repeated at the given interval.

The present invention will now be described more specifically with reference to the drawings attached only by way of example.

### BRIEF DESCRIPTION OF THE DRAWINGS

FIG. 1 is a block diagram for illustrating the transmitter and receiver of a mobile station according to an embodiment of the present invention;

FIG. 2 is a block diagram for illustrating the transmitter and receiver of a mobile station according to another embodiment of the present invention;

FIG. 3 is a block diagram for illustrating a dual PLL according to the present invention.

### DETAILED DESCRIPTION OF THE PREFERRED EMBODIMENT

Turning now to the drawings, the same reference numerals are used to represent similar or identical elements and functional parts for purposes of clarity and ease of understanding. In addition, detailed descriptions of the conventional parts not required to comprehend the technical concept of the present invention are omitted so as not to obscure the present invention.

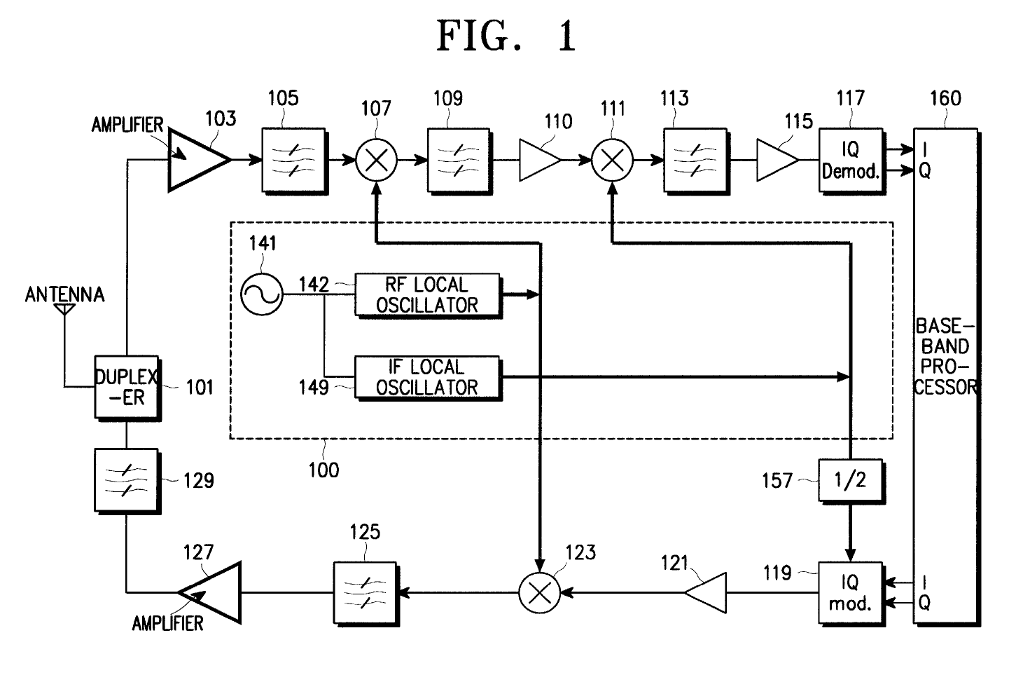

Referring to FIG. 1, duplexer 101 permits alternate transmission and reception using the same radio antenna. In the reception path, a low-noise amplifier 103 amplifies the radio signals from the duplexer 101, and the signal from the low-noise amplifier is filtered through a high-pass filter 105. The filtered signal is mixed with a RFLO from a RF local oscillator 142 in a first mixer 107 to generate an IF signal filtered through a first receiver band-pass filter 109, whose output is then amplified through a first receiver amplifier 110 and applied to a second mixer 111. The second mixer 111 mixes the amplified IF signal and an IFLO from an IF local oscillator 149 to generate a base band signal, which is 13 MHz in the ICO communications system. The base band signal is transferred through a second receiver band-pass filter 113 to a second receiver amplifier 115, and then to an in-phase/quadrature (IQ) demodulator 117 to extract the in-phase data and quadrature data at base-band processor 160.

Meanwhile, in the transmission path, an IQ modulator 119 modulates in-phase data and quadrature data to generate a base band signal, which is inputted with the IFLO received from the IF local oscillator 149 through a ½frequency divider 157 to generate an IF signal amplified by a first transmitter amplifier 121. A third mixer 123 mixes the amplified IF signal and the RFLO from the RF local oscillator 142 to generate an RF signal, whose frequency range is 1985.025 to 2014.975 MHz with a frequency bandwidth of 25 KHz per channel. The RF signal is delivered through a transmitter band-pass filter 125 to a power amplifier 127, and then to a low-pass filter 129 and ultimately to the duplexer 101 for transmission through the antenna.

The dual PLL 100 for generating the IFLO and RFLO comprises a voltage-controlled temperature-compensated crystal oscillator (VCTCXO) 141, RF local oscillator 142, and IF local oscillator 149.

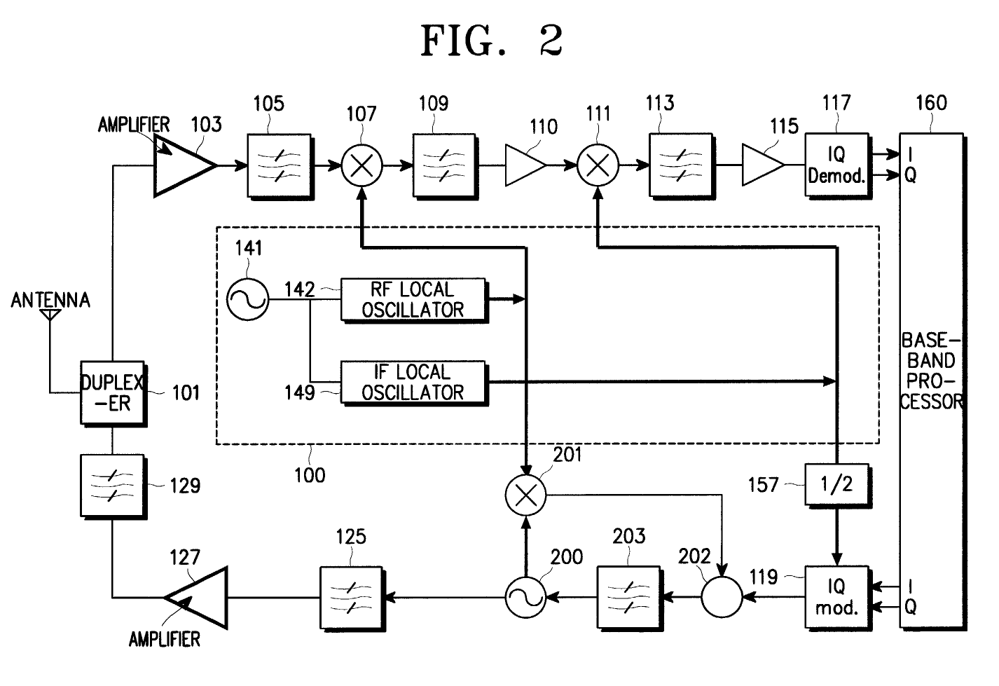

In another embodiment of the present invention, as shown in FIG. 2, an offset PLL is provided to cope with phase errors and noises generated in transmission, which comprises a phase detector 202 connected to the output of the IQ modulator 119, a loop filter 203, a VCO 200, and a mixer 201. The output signal of the VCO 200 is transferred to both transmitter band-pass filter 125 and mixer 201, which produces the differential signal between the output frequency of the VCO 200 and the output frequency of the RF local oscillator 142. In this case, if the output of the mixer 201 corresponds with the output of the IQ modulator 119, the phase detector 202 controls the VCO 200 to deliver the signal to the transmitter band-pass filter 125.

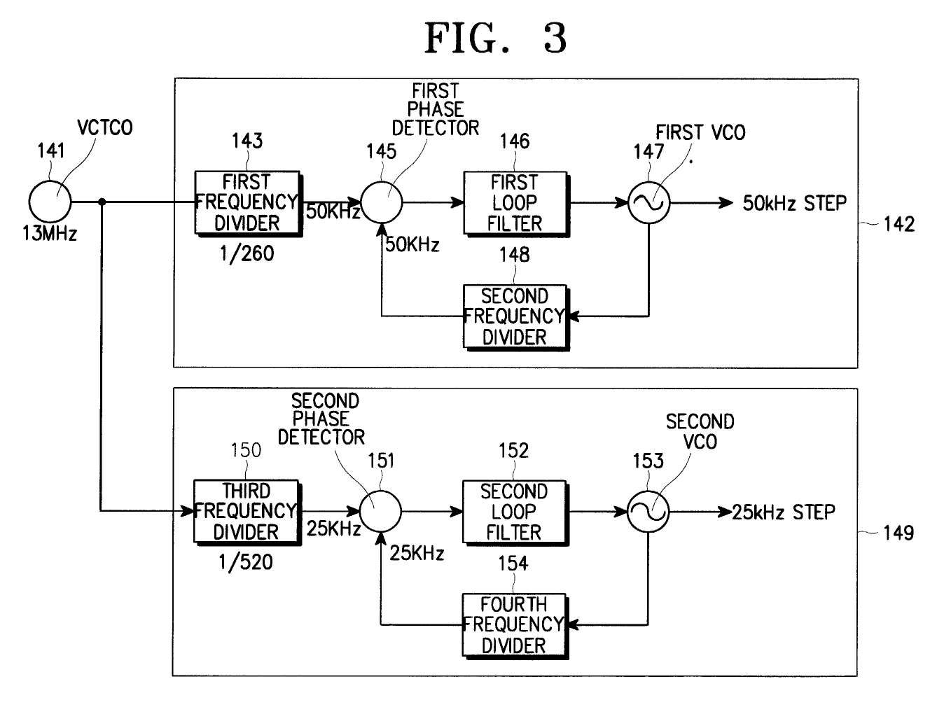

Describing more specifically the structure of the dual PLL 100 of the present invention with reference to FIG. 3, the RF local oscillator 142, as shown in FIGS. 1 and 2, comprises a first frequency divider 143, first phase detector 145, first loop filter 146, second frequency divider 148, and first VCO 147, while the IF local oscillator 149 comprises a third frequency divider 150, second phase detector 151, second loop filter 152, fourth frequency divider 154, and second VCO 153.

The VCTCXO 141 generates a constant frequency, e.g., 13 MHz, compensating for temperature variations of the environment. The output of the VCTCXO 141 is supplied to the first and third frequency dividers 143 and 150. The first frequency divider 143 divides the frequency of 13 MHz by 260 to generate a frequency of 50 KHz. The third frequency divider 150 divides the frequency of 13 MHz by 520 to generate a frequency of 25 KHz. The first phase detector 145 compares the output signal of the first frequency divider 1 of the first VCO 147 fed back to generate a control signal to control the first VCO 147. The first loop filter 146 filters the output signal of the first phase detector 145 to extract the DC component applied to the first VCO 147. The VCO 147 changes the output frequency by an interval of 50 KHz according to the output signal of the first loop filter 146. The second frequency divider 148 divides the output frequency of the first VCO 147 by a predetermined value to generate a divided frequency applied to the input of the first phase detector 145. In this case, the division ratio of the second frequency divider 148 varies with channels as shown in Table 1.

TABLE 1

| Channel | Division Ratio |
|---|---|
| TX CH 1 | 36281 (128*283 + 57) |
| RX CH 1199 | 36900 (128*288 + 36) |

The division ratio of the TX CH1 is calculated by multiplying the prescaler value (128) by the programming counter value (283) and adjusting the total by an optional swallow counter value (57). The division ratio of the RX CH 1199 is calculated by multiplying the prescaler value (128) by the programming counter value (288) and adjusting the total by the optional swallow counter value (36).

The following Table 2 represents the output frequencies of the first VCO 147.

TABLE 2

| Channel | Output Frequency |
|---|---|
| TX RFLO | 1814.05˜1844.0 MHz |
| RX RFLO | 1815.05˜1845.0 MHz |

The output frequency of the first VCO 147 is increased by 50 KHz per increase of two channels.

The second phase detector 151 compares the output signal of the third frequency divider 150 with the output signal of the second VCO 153 fed back to generate a control signal to control the second VCO 153. The second loop filter 152 filters the output signal of the second phase detector 151 to extract the DC component applied to the second VCO 153. The second VCO 153 changes the output frequency by an interval of 25 KHz according to the output signal of the second loop filter 152. The fourth frequency divider 154 divides the output frequency of the second VCO 153 by a predetermined value to generate a divided frequency applied to the input of the second phase detector 151. In this case, the division ratio of the fourth frequency divider 154 varies with channels as shown in Table 3. The division ratio is calculated in a manner similar to that described above with respect to Table 1.

TABLE 3

| Channel | Division Ratio |
|---|---|
| TX Odd Channel 1 | 13678 (64*213 + 46) |
| RX Odd channel 1 | 13679 (64*213 + 47) |
| TX/RX Even Channel | 13680 (64*213 + 48) |

The following Table 4 represents the output frequencies of the second VCO 153.

TABLE 4

| Channel | Output Frequency |
|---|---|
| TX IFLO | 341.950/342.0 MHz |
| RX IFLO | 341.975/342.0 MHz |

In this case, the second VCO 153 generates the odd channel receiving fundamental frequency RXIFLO of 341.975 MHz and the even channel fundamental frequency of 342.0 MHz obtained by adding 25 KHz to the former, independently with channel increase. Likewise, the odd channel transmitting fundamental frequency TXIFLO is 341.950 MHz, and the even channel fundamental frequency 342.0 MHz obtained by adding 50 KHz to the former, independent on channel increase. However, in the case of transmission, the frequency may be considered to have a variation of 25 KHz because the output of the ½frequency divider 157 is used as the IFLO as shown in FIGS. 1 and 2.

The following Tables 5 and 6 represent the frequency planning characteristics of the IFLO and RFLO for transmission and reception of the ICO communications system according to channels.

TABLE 5

| | Transmission | | | |
|---|---|---|---|---|
| Channel | TX-Fc | IFLO | TXIF | RFLO |
| 1 | 1985.025 | 341.950 | 170.975 | 1814.050 |
| 2 | 1985.050 | 342.000 | 171.000 | 1814.050 |
| 3 | 1985.075 | 341.950 | 170.975 | 1814.100 |
| 4 | 1985.100 | 342.000 | 171.000 | 1814.100 |
| 5 | 1985.125 | 341.950 | 170.975 | 1814.150 |
| 6 | 1985.150 | 342.000 | 171.000 | 1814.150 |
| 7 | 1985.175 | 341.950 | 170.975 | 1814.200 |
| 8 | 1985.200 | 342.000 | 171.000 | 1814.200 |
| 9 | 1985.225 | 341.950 | 170.975 | 1814.250 |
| . | . | . | . | . |
| . | . | . | . | . |
| . | . | . | . | . |
| 1197 | 2014.925 | 341.950 | 171.000 | 1843.950 |
| 1198 | 2014.950 | 342.000 | 170.975 | 1843.950 |
| 1199 | 2014.975 | 341.950 | 171.000 | 1844.000 |

In Table 5, Fc represents transmission carrier frequency, IFLO the output frequency of the second VCO 153, TX IFLO the divided frequency of the ½frequency divider 157, and RFLO the output frequency of the first VCO 147.

TABLE 6

| | Reception | | | | |
|---|---|---|---|---|---|
| Channel | RX-Fc | RFLO | IFLO | 1^{st} IF | 2^{nd} IF |
| 1 | 2170.025 | 1815.050 | 341.975 | 354.975 | 13.000 |
| 2 | 2170.050 | 1815.050 | 342.000 | 355.000 | 13.000 |
| 3 | 2170.075 | 1815.100 | 341.975 | 354.975 | 13.000 |
| 4 | 2170.100 | 1815.100 | 342.000 | 355.000 | 13.000 |
| 5 | 2170.125 | 1815.150 | 341.975 | 354.975 | 13.000 |
| 6 | 2170.150 | 1815.150 | 342.000 | 355.000 | 13.000 |
| 7 | 2170.175 | 1815.200 | 341.975 | 354.975 | 13.000 |
| 8 | 2170.200 | 1815.200 | 342.000 | 355.000 | 13.000 |
| 9 | 2170.225 | 1815.250 | 341.975 | 354.975 | 13.000 |
| . | . | . | . | . | . |
| . | . | . | . | . | . |
| . | . | . | . | . | . |
| 1197 | 2199.925 | 1844.950 | 341.975 | 354.975 | 13.000 |
| 1198 | 2199.950 | 1844.950 | 341.975 | 354.975 | 13.000 |
| 1199 | 2199.975 | 1845.000 | 341.975 | 354.975 | 13.000 |

In Table 6, Fc represents the receiving carrier frequency, IFLO the output frequency of the second VOC 153, and RFLO the output frequency of the first VCO 147. In addition, the 1^{st} and 2^{nd} IFs respectively represent the output frequencies of the first 107 and 111 of FIG. 1.

Describing the procedure of generating the frequencies with reference to FIG. 1 and the above tables, the RF local oscillator 142 generates the frequency increased by 50 KHz per increase of two channels. Meanwhile, the IF local oscillator alternately and repeatedly generates two kinds of frequencies with a difference of 25 KHz between the odd and even channels. Namely, the odd channel has a transmitting IFLO of 341.950 MHz and a receiving IFLO 341.975 MHz, while the even channel has a transmitting IFLO of 342.0 MHz and a receiving IFLO 342.0 MHz. Though the difference between both transmitting IFLOs is 50 KHz, the ½frequency divider 157 of FIG. 1 divides its resulting in a difference of 25 KHz, which is the same as the receiving frequencies.

The present embodiment shows the RFLO changed at the interval of two channels, but it may be changed at an interval of more channels. In this case, the IFLO is adjusted to have alternate values at the frequency changing interval of the RFLO, as shown in the following Table 7.

TABLE 7

| Channel | | |
|---|---|---|
| Interval | RFLO | IFLO |
| 2 Channel | 50 KHz | 0,25 |
| 3 Channel | 75 KHz | 0, 25, 50 |
| 2 Channel | 100 KHz | 0, 25, 50, 75 |
| 3 Channel | 125 KHz | 0, 25, 50, 75, 100 |
| . | . | . |
| . | . | . |
| . | . | . |

As shown in Table 7, the invention may be applied to change the RFLO at an interval of more than two channels. To do so, the bandwidth of the loop filter of the IF local oscillator 149 must be changed.

While the present invention has been described in connection with specific embodiments accompanied by the attached drawings, it will be readily apparent to those skilled in the art that various changes and modifications may be made thereto without departing from the spirit and scope of the present invention, as defined by the appended claims.

What is claimed is:

1. A method for generating frequencies in a dual phase locked loop (PLL), comprising the steps of:
generating radio frequency local oscillations (RFLOs) sequentially increased in the bandwidth at a given interval of more than two channels; and
generating a group of intermediate frequency local oscillations (IFLOs) gradually increased from a reference frequency channel by channel in said given interval, wherein said group of IFLOs are sequentially repeated at said given interval.

2. A method as defined in claim 1, wherein said dual PLL comprises:
a voltage-controlled temperature-compensated oscillator (VCTCXO);
a first PLL part having a first frequency divider connected to a first phase detector, a first loop filter connected to said first phase detector, a first voltage-controlled oscillator (VCO) connected to said first loop filter, and a second frequency divider connected between said first VCO and first phase detector; and
a second PLL part having a third frequency divider connected to a second phase detector, a second loop filter connected to said second phase detector, a second VCO connected to said second loop filter, and a fourth frequency divider connected between said second VCO and second phase detector;
said first and second PLL part being connected to said VCTCXO.

3. A method as defined in claim 2, wherein said dual PPL further includes a first mixer for mixing the output signal of said RFLO and a received signal to generate a first mixed signal, and a second mixer for mixing the output signal of said IFLO and said first mixed signal.

4. A method as defined in claim 3, wherein said dual PLL further includes a fifth frequency divider for dividing said IFLOs by two, an in-phase/quadrature (I/Q) modulator for modulating in-phase data and quadrature data, a third phase detector connected to said I/Q modulator, a third loop filter connected to said third phase detector, a third VCO connected to said third loop filter, and a third mixer for mixing the output signal of said third VCO and said RFLO.

5. A method as defined in claim 1, wherein said given interval is two channel bandwidths equal 50 KHz.

6. A method as defined in claim 5, wherein said IFLOs alternate between a reference frequency and a frequency obtained by adding 25 KHz to said reference frequency with channels sequentially increased.

7. A method as defined in claim 4, wherein frequency planning of said dual PLL for transmission and reception is as shown in the following Tables 8 and 9:
TABLE 8

| | Transmission | | | |
|---|---|---|---|---|
| Channel | TX-Fc | IFLO | TXIF | RFLO |
| 1 | 1985.025 | 341.950 | 170.975 | 1814.050 |
| 2 | 1985.050 | 342.000 | 171.000 | 1814.050 |
| 3 | 1985.075 | 341.950 | 170.975 | 1814.100 |
| 4 | 1985.100 | 342.000 | 171.000 | 1814.100 |
| 5 | 1985.125 | 341.950 | 170.975 | 1814.150 |
| 6 | 1985.150 | 342.000 | 171.000 | 1814.150 |
| 7 | 1985.175 | 341.950 | 170.975 | 1814.200 |
| 8 | 1985.200 | 342.000 | 171.000 | 1814.200 |
| 9 | 1985.225 | 341.950 | 170.975 | 1814.250 |
| . | . | . | . | . |
| . | . | . | . | . |
| . | . | . | . | . |
| 1197 | 2014.925 | 341.950 | 171.000 | 1843.950 |
| 1198 | 2014.950 | 342.000 | 170.975 | 1843.950 |
| 1199 | 2014.975 | 341.950 | 171.000 | 1844.000 |

TABLE 9

| | Reception | | | | |
|---|---|---|---|---|---|
| Channel | RX-Fc | RFLO | IFLO | 1^{st} IF | 2^{nd} IF |
| 1 | 2170.025 | 1815.050 | 341.975 | 354.975 | 13.000 |
| 2 | 2170.050 | 1815.050 | 342.000 | 355.000 | 13.000 |
| 3 | 2170.075 | 1815.100 | 341.975 | 354.975 | 13.000 |
| 4 | 2170.100 | 1815.100 | 342.000 | 355.000 | 13.000 |
| 5 | 2170.125 | 1815.150 | 341.975 | 354.975 | 13.000 |
| 6 | 2170.150 | 1815.150 | 342.000 | 355.000 | 13.000 |
| 7 | 2170.175 | 1815.200 | 341.975 | 354.975 | 13.000 |
| 8 | 2170.200 | 1815.200 | 342.000 | 355.000 | 13.000 |
| 9 | 2170.225 | 1815.250 | 341.975 | 354.975 | 13.000 |
| . | . | . | . | . | . |
| . | . | . | . | . | . |
| . | . | . | . | . | . |
| 1197 | 2199.925 | 1844.950 | 341.975 | 354.975 | 13.000 |
| 1198 | 2199.950 | 1844.950 | 341.975 | 354.975 | 13.000 |
| 1199 | 2199.975 | 1845.000 | 341.975 | 354.975 | 13.000 |

wherein TX-Fc represents transmission carrier frequency,
IFLO represents the output frequency of the second VCO,
TXIF represents the divided frequency of the fifth frequency divider,
RFLO represents the output frequency of the first VCO,
RX-Fc represents the receiving carrier frequency,
1^{st} IF represents the output frequency of the first mixer, and
2^{nd} IF represents the output frequency of the second mixer.

8. A method for generating frequencies in a dual PLL, comprising the steps of:
generating RFLOs sequentially increased in the bandwidth at a given interval of two channel bandwidths; and
alternately generating a reference frequency and a frequency obtained by adding one channel bandwidth to said reference frequency with channels sequentially increased.

9. A method as defined in claim 8, wherein said two channel bandwidths equal to 50 KHz.

10. A method as defined in claim 8, wherein said reference frequency and said obtained frequency are IFLOs which alternate between said reference frequency and a frequency obtained by adding 25 KHz to said reference frequency with channels sequentially increased.

11. A method as defined in claim 8, wherein said dual PLL comprises:
a voltage-controlled temperature-compensated oscillator (VCTCXO);
a first PLL part having a first frequency divider connected to a first phase detector, a first loop filter connected to said first phase detector, a first voltage-controlled oscillator (VCO) connected to said first loop filter, and a second frequency divider connected between said first VCO and first phase detector; and
a second PLL part having a third frequency divider connected to a second phase detector, a second loop filter connected to said second phase detector, a second VCO connected to said second loop filter, and a fourth frequency divider connected between said second VCO and second phase detector;
said first and second PLL part being connected to said VCTCXO.

12. A method as defined in claim 11, wherein said dual PPL further includes a first mixer for mixing the output signal of said RFLO and a received signal to generate a first mixed signal, and a second mixer for mixing the output signal of said IFLO and said first mixed signal.

13. A method as defined in claim 12, wherein said dual PLL further includes a fifth frequency divider for dividing said IFLOs by two, an in-phase/quadrature (I/Q) modulator for modulating in-phase data and quadrature data, a third phase detector connected to said I/Q modulator, a third loop filter connected to said third phase detector, a third VCO connected to said third loop filter, and a third mixer for mixing the output signal of said VCO and said RFLO.

14. A method as defined in claim 13, wherein frequency planning of said dual PLL for transmission and reception is as shown in the following Tables 10 and 11:
TABLE 10

| | Transmission | | | |
|---|---|---|---|---|
| Channel | TX-Fc | IFLO | TXIF | RFLO |
| 1 | 1985.025 | 341.950 | 170.975 | 1814.050 |
| 2 | 1985.050 | 342.000 | 171.000 | 1814.050 |
| 3 | 1985.075 | 341.950 | 170.975 | 1814.100 |
| 4 | 1985.100 | 342.000 | 171.000 | 1814.100 |
| 5 | 1985.125 | 341.950 | 170.975 | 1814.150 |
| 6 | 1985.150 | 342.000 | 171.000 | 1814.150 |
| 7 | 1985.175 | 341.950 | 170.975 | 1814.200 |
| 8 | 1985.200 | 342.000 | 171.000 | 1814.200 |
| 9 | 1985.225 | 341.950 | 170.975 | 1814.250 |
| . | . | . | . | . |
| . | . | . | . | . |
| . | . | . | . | . |
| 1197 | 2014.925 | 341.950 | 171.000 | 1843.950 |
| 1198 | 2014.950 | 342.000 | 170.975 | 1843.950 |
| 1199 | 2014.975 | 341.950 | 171.000 | 1844.000 |

TABLE 11

| | Reception | | | | |
|---|---|---|---|---|---|
| Channel | RX-Fc | RFLO | IFLO | 1^{st} IF | 2^{nd} IF |
| 1 | 2170.025 | 1815.050 | 341.975 | 354.975 | 13.000 |
| 2 | 2170.050 | 1815.050 | 342.000 | 355.000 | 13.000 |
| 3 | 2170.075 | 1815.100 | 341.975 | 354.975 | 13.000 |
| 4 | 2170.100 | 1815.100 | 342.000 | 355.000 | 13.000 |
| 5 | 2170.125 | 1815.150 | 341.975 | 354.975 | 13.000 |
| 6 | 2170.150 | 1815.150 | 342.000 | 355.000 | 13.000 |
| 7 | 2170.175 | 1815.200 | 341.975 | 354.975 | 13.000 |
| 8 | 2170.200 | 1815.200 | 342.000 | 355.000 | 13.000 |
| 9 | 2170.225 | 1815.250 | 341.975 | 354.975 | 13.000 |
| . | . | . | . | . | . |
| . | . | . | . | . | . |
| . | . | . | . | . | . |
| 1197 | 2199.925 | 1844.950 | 341.975 | 354.975 | 13.000 |
| 1198 | 2199.950 | 1844.950 | 341.975 | 354.975 | 13.000 |
| 1199 | 2199.975 | 1845.000 | 341.975 | 354.975 | 13.000 |

wherein TX-FC represents transmission carrier frequency,
IFLO represents the output frequency of the second VCO,
TXIF represents the divided frequency of the fifth frequency divider,
RFLO represents the output frequency of the first VCO,
RX-Fc represents the receiving carrier frequency,
1^{st} IF represents the output frequency of the first mixer, and
2^{nd} IF represents the output frequency of the second mixer.

15. A method for generating frequencies in a dual PLL, comprising the steps of:
generating RFLOs sequentially increased in the bandwidth at a given interval of two channel bandwidths;
alternately generating a receiving reference frequency and an receiving IFLO obtained by adding one channel bandwidth to said receiving reference frequency with channels sequentially increased; and
alternately generating a transmitting reference frequency and a transmitting IFLO obtained by adding two channel bandwidths to said transmitting reference frequency, said transmitting IFLO being divided by two.

16. A method as defined in claim 15, wherein said dual PLL comprises:
a voltage-controlled temperature-compensated oscillator (VCTCXO);
a first PLL part having a first frequency divider connected to a first phase detector, a first loop filter connected to said first phase detector, a first voltage-controlled oscillator (VCO) connected to said first loop filter, and a second frequency divider connected between said first VCO and first phase detector; and
a second PLL part having a third frequency divider connected to a second phase detector, a second loop filter connected to said second phase detector, a second VCO connected to said second loop filter, and a fourth frequency divider connected between said second VCO and second phase detector;
said first and second PLL part being connected to said VCTCXO.

17. A method as defined in claim 16, wherein said dual PPL further includes a first mixer for mixing the output signal of said RFLO and a received signal to generate a first mixed signal, and a second mixer for mixing the output signal of said IFLO and said first mixed signal.

18. A method as defined in claim 17, wherein said dual PLL further includes a fifth frequency divider for dividing said IFLOs by two, an in-phase/quadrature (I/Q) modulator for modulating in-phase data and quadrature data, a third phase detector connected to said I/Q modulator, a third loop filter connected to said third phase detector, a third VCO connected to said third loop filter, and a third mixer for mixing the output signal of said VCO and said RFLO.

19. A method as defined in claim 18, wherein frequency planning of said dual PLL for transmission and reception is as shown in the following Tables 12 and 13:
TABLE 12

| | Transmission | | | |
|---|---|---|---|---|
| Channel | TX-Fc | IFLO | TXIF | RFLO |
| 1 | 1985.025 | 341.950 | 170.975 | 1814.050 |
| 2 | 1985.050 | 342.000 | 171.000 | 1814.050 |
| 3 | 1985.075 | 341.950 | 170.975 | 1814.100 |
| 4 | 1985.100 | 342.000 | 171.000 | 1814.100 |
| 5 | 1985.125 | 341.950 | 170.975 | 1814.150 |
| 6 | 1985.150 | 342.000 | 171.000 | 1814.150 |
| 7 | 1985.175 | 341.950 | 170.975 | 1814.200 |
| 8 | 1985.200 | 342.000 | 171.000 | 1814.200 |
| 9 | 1985.225 | 341.950 | 170.975 | 1814.250 |
| . | . | . | . | . |
| . | . | . | . | . |
| . | . | . | . | . |
| 1197 | 2014.925 | 341.950 | 171.000 | 1843.950 |
| 1198 | 2014.950 | 342.000 | 170.975 | 1843.950 |
| 1199 | 2014.975 | 341.950 | 171.000 | 1844.000 |

TABLE 13

| | Reception | | | | |
|---|---|---|---|---|---|
| Channel | RX-Fc | RFLO | IFLO | 1^{st} IF | 2^{nd} IF |
| 1 | 2170.025 | 1815.050 | 341.975 | 354.975 | 13.000 |
| 2 | 2170.050 | 1815.050 | 342.000 | 355.000 | 13.000 |
| 3 | 2170.075 | 1815.100 | 341.975 | 354.975 | 13.000 |
| 4 | 2170.100 | 1815.100 | 342.000 | 355.000 | 13.000 |
| 5 | 2170.125 | 1815.150 | 341.975 | 354.975 | 13.000 |
| 6 | 2170.150 | 1815.150 | 342.000 | 355.000 | 13.000 |
| 7 | 2170.175 | 1815.200 | 341.975 | 354.975 | 13.000 |
| 8 | 2170.200 | 1815.200 | 342.000 | 355.000 | 13.000 |
| 9 | 2170.225 | 1815.250 | 341.975 | 354.975 | 13.000 |
| . | | . | . | . | . |
| . | | . | . | . | . |
| . | | . | . | . | . |
| 1197 | 2199.925 | 1844.950 | 341.975 | 354.975 | 13.000 |
| 1198 | 2199.950 | 1844.950 | 341.975 | 354.975 | 13.000 |
| 1199 | 2199.975 | 1845.000 | 341.975 | 354.975 | 13.000 |

Wherein TX-Fc represents transmission carrier frequency,
IFLO represents the output frequency of the second VCO,
TXIF represents the divided frequency of the fifth frequency divider,
RFLO represents the output frequency of the first VCO,
RX-Fc represents the receiving carrier frequency,
1^{st} IF represents the output frequency of the first mixer, and
2^{nd} IF represents the output frequency of the second mixer.
